(19) United States
(12) Patent Application Publication
(10) Pub. No.: US 2023/0025522 A1
(43) Pub. Date: Jan. 26, 2023

(54) PROCESS OPTIMIZATION USING MIXED INTEGER NONLINEAR PROGRAMMING

(71) Applicant: AVEVA Software, LLC, Lake Forest, CA (US)

(72) Inventors: Purt Tanartkit, Yorba Linda, CA (US); Rajkumar Vedam, Katy, TX (US); Kishore Kumar Hemachandran, Peravallur, Chennai (IN); Pranav Bhaswanth Madabhushi, Telangana (IN); Sankararao Boddupalli, Hyderabad (IN); Mallikarjun A. Lavate, New Town Bangalore (IN); Detong Zhang, Houston, TX (US)

(21) Appl. No.: 17/729,548

(22) Filed: Apr. 26, 2022

Related U.S. Application Data
(63) Continuation of application No. 16/841,178, filed on Apr. 6, 2020, now abandoned.
Application No. 16/841,178 is a continuation of application No. 14/745,961, filed on Jun. 22, 2015, now abandoned.

(51) Int. Cl. G05B 13/04; G06F 17/11; G06F 30/20

(52) U.S. Cl. CPC G05B 13/041; G06F 17/11; G06F 30/20

(57) ABSTRACT

Real-time dynamic optimization of a process model in an online model-based process control computing environment. A mixed integer nonlinear programming (MINLP) solver utilizes a switch to activate and deactivate a first-principle model of a process unit. The switch enables MINLP behavior by attaching to the first-principle model.

### BACKGROUND

Conventional tools for continuous process optimization employ calculations designed to determine optimal operating states of continuous processes, such as refinery, chemical, or petrochemical plant operations. When an optimal decision requires the switching on or switching off of units, conventional tools for continuous optimization are at a disadvantage because they cannot adequately retreat from a locally converged state or explore potential new states. Additionally, conventional tools necessitate a workflow in which a user sets up case studies for each state and manually explores each case study for optimality. For example, a small process with only five switchable units would have thirty-two (i.e., 2⁵) possible operating states. As such, the number of possible operating states and, by extension, the difficulty of determining the optimal process operating state, increases exponentially as the number of units increases linearly. Accordingly, conventional solutions require a process engineer to use intuition to select a small number of possible operating states on which to conduct case studies. These conventional systems and methods are rigid, unable to offer optimal strategies that quickly account for changing process parameters (e.g., changing energy costs).

SimSci ROMeo, available from Schneider Electric, is a Rigorous On-line Modeling and Equation-based Optimization (ROMEO) module for continuous process optimization.

### SUMMARY

Aspects of the present invention improve the fields of process control and automation and process simulation by employing online first-principles simulation techniques in conjunction with a Mixed Integer Nonlinear Programming (MINLP) solver in real-time to provide optimization of nonlinear continuous processes that incorporate switchable units. In an embodiment, this approach allows the determination of an optimal operating state while taking into account changing process parameters without requiring case studies that model switchable units to be taken offline. Aspects of the present invention also provide improvements in computer technology, namely, process model simulation and optimization.

In an aspect, a computer-implemented method for determining an optimal operating state of a continuous process includes receiving, by a control system including a processor, data from a sensor within the continuous process. The data represents a current state of a process unit within the continuous process. The method further includes simulating an operation of at least one unit model in conjunction with an MINLP solver in real-time by the control system. The unit model represents the process unit via at least one first-principle equation. Further, the control system switches the unit model between an active state and an inactive state during the simulating. The control system also generates an operating state of the continuous process that satisfies at least one operating constraint of the continuous process based on the simulating and the switching.

In another aspect, a system comprises a sensor that generates data representing a current state of a process unit comprising a continuous process. The system also includes a control system, which in turn includes a model component, a switch component, and an MINLP solver component. The model component comprises at least one first-principle equation that represents the process unit. The switch component comprises the model component.

In yet another aspect, a computer-readable storage device has computer-executable modules stored thereon for determining an operating state of a continuous process. The modules include a model module, an MINLP switch module, and a solver module. The model module defines a unit model that represents a process unit within the continuous process via at least one first-principle equation during an execution of the model module by a processor. The MINLP switch module transitions the model module between an active state and an inactive state during execution by the processor. The solver module simulates an operation of the model module and the MINLP switch module in real-time during execution by the processor.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Other objects and features will be in part apparent and in part pointed out hereinafter.

### BRIEF DESCRIPTION OF THE DRAWINGS

FIG. 1 is a block diagram of an exemplary invasive MINLP modeling and solver system in accordance with an embodiment of the invention.

FIG. 2 is a block diagram of an exemplary MINLP modeling and solver system including a non-invasive MINLP switch in accordance with an embodiment of the invention.

FIG. 3A is a diagram illustrating a graphical user interface of MINLP configuration parameters in accordance with an embodiment of the invention.

FIG. 3B is a diagram illustrating a graphical user interface of MINLP data entry parameters in accordance with an embodiment of the invention.

FIG. 4 is a block diagram of an exemplary MINLP modeling and solver system in an exemplary continuous process in accordance with an embodiment of the invention.

FIG. 5 is a flowchart of an exemplary ROMEO execution operation in accordance with an embodiment of the invention.

FIG. 6 is a flowchart of an exemplary MINLP execution operation in accordance with an embodiment of the invention.

Corresponding reference characters indicate corresponding parts throughout the drawings.

### DETAILED DESCRIPTION

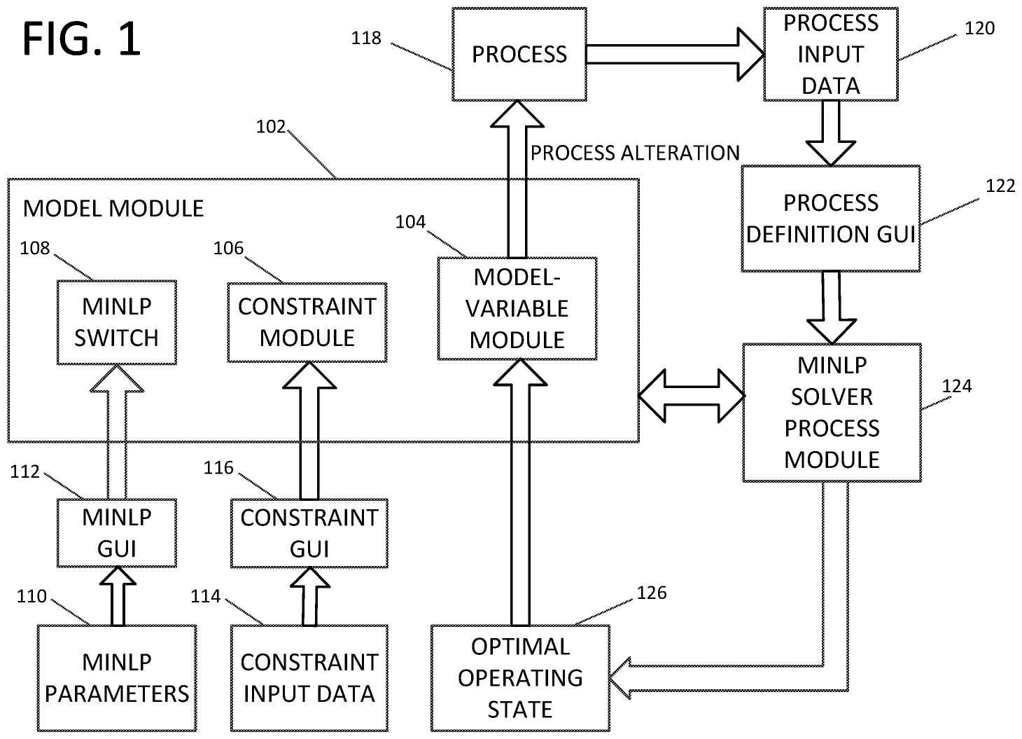

Referring now to the drawings, FIG. 1 is a block diagram of a ROMEO solver system embodying aspects of the invention, including implementing Mixed Integer Nonlinear Programming (MINLP) behavior. In one form, computer-executable instructions are executed to solve a process problem by an MINLP switch in conjunction with constraints of a model that can simulate the behavior of desired process units. The illustrated system includes a model module 102, a model-variable module 104, a constraint module 106, an invasive MINLP switch 108, MINLP parameters 110, an MINLP interface 112, constraint input data 114, a constraint interface 116, a process 118, process input data 120, a process definition interface 122, a solver module 124, and an optimal operating state 126. In an embodiment, FIG. 1 illustrates an invasive MINLP modeling system and method.

Systems and methods described herein solve nonlinear process problems while optimizing for certain considerations (e.g., operating penalty, cost, etc.) while ensuring the process meets plant constraints. Aspects of the present invention are described herein with respect to optimizing energy source usage in a continuous process but it is to be understood by one skilled in the art that the systems and methods described herein are also capable of optimizing continuous processes with respect to considerations other than energy source usage.

Energy source (e.g., utility) optimization in continuous processes involves calculating the best solution to meet the energy demand, while operating the underlying process optimally with desired operational specifications and keeping the operational expenses as low as possible. In order to perform a quantum of work in a process, there is a need for some amount of energy. The utility optimization problem is relevant when there are multiple energy sources that can supply the desired quantum of energy. For example, there may be some sources of energy endemic to the process and other sources of energy that are extraneous to the process. Utility optimization requires the capability to switch among available energy sources depending on the economics, energy and material balance, and underlying nonlinear process optimality. These computational issues require an MINLP solver in conjunction with models that can simulate the switching behavior of process units. Modeling for MINLP utility optimization is the subject of aspects of the present invention.

As an illustrative example, a process requires one hundred units of energy (i.e., E=100) to perform an amount of work (W). The following table illustrates four energy sources capable of supplying the required energy units along with the minimum and maximum amount of energy each source can supply and the cost per unit of energy supplied for each source:

| Energy | | | |
|---|---|---|---|
| Source | Minimum | Maximum | Cost |
| S1 | 0 | 25 | 10 |
| S2 | 10 | 50 | 5 |
| S3 | 10 | 25 | 15 |
| S4 | 0 | 25 | 5 |

One exemplary solution is to use 50 units of source S2, 25 units of source S4, 10 units of source S3, and 15 units of source S1 (i.e., 50*S2+25*S4+10*S3+15*S1=100) such that the lowest cost sources (i.e., S2 and S4) are each loaded to the maximum, the minimum loading constraint on the highest cost source (i.e., S3) is obeyed, and the slack is picked up with the remaining source (i.e., S1).

This illustrative example has two aspects. First, an energy source could be independent of the process (e.g., electricity powering a motor) and thus loading is a linear function of the costs and specified loading constraints. Second, an energy source could be a byproduct of the process such as residual steam as a byproduct of a heat exchanger (e.g., captured steam powering a steam turbine), for example. This second energy source would be endemic to the process and loading such a source would impact the equilibrium and cost of operation of the underlying process itself. Continuing the example above, steam generated as a byproduct of the process can be added as a fifth energy source:

| Energy | | | |
|---|---|---|---|
| Source | Minimum | Maximum | Cost |
| S1 | 0 | 25 | 10 |
| S2 | 10 | 50 | 5 |
| S3 | 10 | 25 | 15 |
| S4 | 0 | 25 | 5 |
| S5 | 10 | 100 | Variable |

Initially, the steam (i.e., source S5) might meet fifty units of energy and be the cheapest source of energy. A process optimizer would then attempt to make source S5 meet the additional fifty units of energy. This attempt would involve operating the process at a different operating point to generate the additional fifty units of energy and would therefore change the cost of production of the steam, which is a nonlinear function of the process. In other words, the steam initially looks like an attractive energy source because of its low cost, but generating enough additional steam to create enough energy to meet the full requirement of one hundred units has an associated process cost that might actually make the steam a more expensive energy source than an alternative energy source. Accordingly, aspects of the present invention described herein solve the utility optimization problem by providing the capability to switch among various energy supplying units depending on the associated economics while also achieving energy balance and underlying nonlinear process optimality.

The utility optimization problem solved by aspects of the present invention can be expressed in general mathematical form. Consider a nonlinear process modeled with equality constraints f(x,y,z)=0, where the function f is nonlinear in the vector variables x, y, and z. Let f: R^{N}×R^{S}×B^{B}->R^{N}, illustrating the dimension of these quantities, where typically, S<N. The variable x is free-dependent and can be varied between some operational bounds of the process. The variable y is free-independent variables and usually referred to as a “specification” and also varied between bounds of the process. The vector variable z is free-independent and is the vector of integer switches in the problem. In an embodiment, variable z varies between [0, 1]. Given a cost function c(x,y,z), the utility optimization problem is:

min_{x,y,z}c(x,y,z)

subject to

f(x,y,z)=0

and

xₘᵢₙ≤x≤xₘₐₓ, yₘᵢₙ≤y≤yₘₐₓ and z∈B^{B} (Equation 1)

A Rigorous Online Modeling and Equation-based Optimization (ROMEO) modeling system, as described herein, allows a user to construct a flowsheet of the process with models or units from a pre-built library or from models built by the user. These models encode the quantities f, c, x, and y in Equation 1. Aspects of the present invention described herein encompass the addition of models that encode the z variable in Equation 1.

Referring further to FIG. 1, in an embodiment, the model module 102 comprises a storage memory device having stored thereon processor-executable instructions for defining a first-principle model of a unit comprising a continuous process that has been modified to implement MINLP behavior. In an exemplary embodiment, model module 102 defines a first-principle model of a motor in the process 118 and includes the model-variable module 104, the constraint module 106, and the invasive MINLP switch 108. For instance, the first-principle model of model module 102 defining the motor includes a modified energy balance equation:

MINLPShaftPower−ElectPower*Efficiency=0 (Equation 2)

where MINLPShaftPower is an unbounded free-dependent variable as further described below, ElectPower is the electrical input power to the motor, and Efficiency is the energy conversion efficiency of the motor. Additional energy-supplying units include, but are not limited to, generators, steam turbines, and boiler fuel flows.

Still referring to FIG. 1, the model-variable module 104 comprises, in an embodiment, a storage memory device having stored thereon process-executable instructions for defining a model-variable of the first-principle model of model module 102. In an exemplary embodiment, model-variable module 104 defines the shaft power of a motor as the model-variable of interest. Other model-variables include, but are not limited to, the shaft power of a generator, the actual work of a steam turbine, and flow rate of boiler fuel flows.

In one embodiment of the present invention, the constraint module 106 comprises a storage memory device having stored thereon processor-executable instructions for defining one or more constraints of the first-principle model of model module 102. In an exemplary embodiment, constraint module 106 defines a minimum value (e.g., 0) and a maximum value (e.g., 100) of the shaft power of a motor.

The invasive MINLP switch 108 of FIG. 1 comprises a storage memory device having stored thereon processor-executable instructions for implementing MINLP behavior in the first-principle model of model module 102, in an exemplary embodiment. In this instance, invasive MINLP switch 108 implements MINLP behavior in a motor model defined by model module 102 by modifying the shaft power of the motor. The exemplary invasive MINLP switch 108 includes the equation:

MINLPShaftPower−MINLPBinary*ShaftPower=0 (Equation 3)

where MINLPShaftPower is an unbounded free-dependent variable, MINLPBinary is a free-independent variable in MINLP Optimization mode bounded by [0, 1], and ShaftPower is the mechanical output of the motor. As indicated by Equation 3, when MINLPBinary equals zero then MINLPShaftPower also equals zero (i.e., MINLPBinary=0, MINLPShaftPower=0), and when MINLPBinary equals one then MINLPShaftPower equals ShaftPower (i.e., MINLPBinary=1, MINLPShaftPower=ShaftPower). By defining the motor in this way, invasive MINLP switch 108 ensures that the signals exported for outside connections to other process units are properly processed for MINLP. Binding MINLPBinary by [0, 1] allows the value of ShaftPower to update as it changes during operation of the continuous process (i.e., the motor does not need to be turned off in the continuous process) while simultaneously allowing MINLPShaftPower to simulate the motor being turned off in Equation 2 during simulation of the process, as described below.

Referring again to FIG. 1, the MINLP interface 112 receives MINLP parameters 110 from a source such as a user, another software program, or a device, for example. The MINLP interface 112 provides received MINLP parameters 110 to invasive MINLP switch 108. The invasive MINLP switch 108 uses the received MINLP parameters 110 to customize the MINLP behavior of the first-principle model of model module 102. In an exemplary embodiment, MINLP interface 112 is a graphical user interface (GUI) that allows a user to set a threshold for switching based upon parameters including a startup cost, a shutdown cost, and time period, as further described herein.

The constraint interface 116 of FIG. 1 receives constraint input data 114 from a source such as a user, another software program, or a device, for example. The constraint interface 116 provides the received constraint input data 114 to constraint module 106. The constraint module 106 uses the received constraint input data 114 to define the constraints of the first-principle model of model module 102. In an exemplary embodiment, constraint interface 116 is a GUI that allows a user to set constraints such as a minimum and maximum shaft power, for example, of a motor which model module 102 defines.

According to embodiments of the invention, process 118 is a continuous process, such as a refinery, chemical, or petrochemical plant operation, for example, and/or its control system. Other aspects of process 118 are further defined herein. The process definition interface 122 receives process input data 120 from a source such as a user, another software program, or a device (e.g., a sensor and/or a unit in process 118), for example. The process input data 120 represents a current state of process 118 and corresponds to the process problem to be solved. The process definition interface 122 provides the received process input data 120 to the solver module 124 for use in executing an interactive model to solve the process problem as described herein. In an exemplary embodiment, process definition interface 122 is part of a ROMEO modeling system that allows a user to construct a flowsheet of process 118 with models or units from a pre-built library or from models built by the user.

The solver module 124 comprises a storage memory device having stored thereon processor-executable instructions for defining an iterative process having variables. The variables have certain values which, when applied to the iterative process, converge the iterative process to a solution. The variables have other values, which, when applied to the iterative process, do not converge the iterative process to a solution. In one form, solver module 124 comprises a ROMEO module. In another form, solver module 124 is an MINLP solver module. The solver module 124 is adapted for changing the value of the MINLPBinary variable in order to switch model module 102 on and off in the simulation while converging to an optimal solution (e.g., optimal operating state 126) for the underlying nonlinear process 118. Commonly assigned U.S. patent application Ser. No. 13/968,119, which describes a nonlinear correction factor module for use with, for example, a ROMEO solver, is incorporated by reference in its entirety.

In operation of an exemplary embodiment illustrated by FIG. 1, the processor-executable instructions of invasive MINLP switch 108 implement Equation 3 and the processor-executable instructions of model module 102 implement Equation 2. The MINLP interface 112 receives an MINLP parameter 110 that indicates shaft power as the model variable of interest of a motor defined by model module 102. By implementing Equation 2 with model module 102, ElectPower goes to zero when MINLPShaftPower goes to zero. This action results in the line current also going to zero and correctly simulating the motor having been turned off while the actual shaft power of the motor in process 118 (i.e., ShaftPower) is not altered. In this exemplary embodiment, the economics of the motor are based on the ElectPower variable and therefore no modification is needed to that portion of Equation 2. In the simulated process, the connection of the motor to the shaft is through a gear-box module that is modified to accept MINLPShaftPower, rather than ShaftPower. This ensures that the outside-connected objects in the model flowsheet of process definition interface 122 will see the shaft power go to zero if the simulated motor is turned off in the simulation via changing MINLPShaftPower. It is to be understood by one skilled in the art that an exactly similar modeling process can be utilized to implement MINLP behavior with a generator model.

In another exemplary embodiment of FIG. 1, a steam turbine model can be modified to implement MINLP behavior. In this embodiment, a model variable ActualWork is modified to implement MINLP behavior via a variable MINLPActualWork in the steam turbine model:

MINLPActualWork−MINLPBinary*ActualWork=0 (Equation 4)

where MINLPActualWork is an unbounded free-dependent variable, MINLPBinary is a free-independent variable in MINLP Optimization mode bounded by [0, 1], and ActualWork is the amount of work done by the turbine. As indicated by Equation 4, when MINLPBinary equals zero then MINLPActualWork also equals zero (i.e., MINLPBinary=0, MINLPActualWork=0), and when MINLPBinary equals one then MINLPActualWork equals ActualWork (i.e., MINLPBinary=1, MINLPActualWork=ActualWork). Equation 4 works in tandem with an enthalpy balance equation of model module 102 modified to accept its MINLP behavior:

MINLPActualWork−Feed: MolarFlow*(Feed: Prop[Enth]−Product: Prop[Enth])=0 (Equation 5)

where MINLPActualWork is the unbounded free-dependent variable described above, Feed:MolarFlow is the molar flow rate of steam entering the turbine, Feed:Prop[Enth] is the amount of enthalpy entering the turbine, and Product:Prop[Enth] is the amount of enthalpy leaving the turbine. Binding MINLPBinary by [0, 1] in Equation 4 allows the value ofActualWork to update as it changes during operation of process 118 (i.e., the steam turbine does not need to be turned off in the continuous process) while allowing MINLPActualWorkto simulate the steam turbine being turned off in Equation 5 during simulation of process 118. During simulation of the process, MINLPActualWork is exported to a gear box module connected to the turbine in the model flowsheet of process definition interface 122 so that outside-connected objects in the model flowsheet will see the actual work of the turbine go to zero when the turbine is switched off in the simulation via changing MINLPActualWork.

In yet another exemplary embodiment of FIG. 1, a boiler fuel flow model can be modified to implement MINLP behavior. This modification is provided by the equation:

v_{MINLPFlow}−MINLPBinary*v_{F1ow}==0 (Equation 6)

where v_{MINLPFIow} is an unbounded free-dependent variable, MINLPBinary is a free-independent variable in MINLP Optimization mode bounded by [0, 1], and v_{Flow} is the velocity of the flow of boiler fuels.

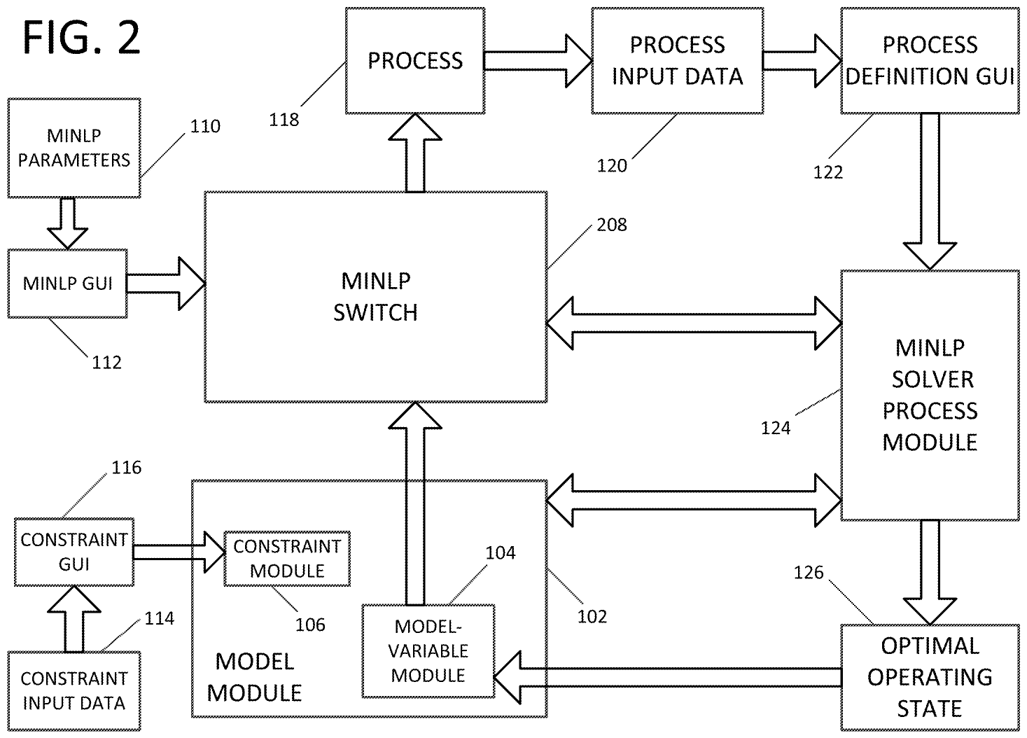

FIG. 2 is a block diagram of another example of a ROMEO solver system and method. In one form, a system and method for solving a process problem by a Mixed Integer Nonlinear Programming (MINLP) switching module in conjunction with models that can simulate the switching behavior of desired process units is illustrated. The illustrated diagram includes the model module 102, a non-invasive MINLP switch 208, MINLP parameters 110, the MINLP interface 112, constraint input data 114, the constraint interface 116, the process 118, process input data 120, the process definition interface 122, the solver module 124, and the optimal operating state 126. The model module 102 includes the model-variable module 104 and the constraint module 106. The non-invasive MINLP switch 208 also includes the model-variable module 104. In an embodiment, FIG. 2 illustrates a non-invasive MINLP modeling system and method.

In one aspect, the non-invasive MINLP switch 208 illustrated by FIG. 2 functions as a non-process MINLP switch unit that encodes the MINLP behavior in a process unit (e.g., model module 102) by identifying a model-variable (e.g., model-variable module 104) to which it attaches and modifies. In this aspect, non-invasive MINLP switch 208 does not utilize a modified variable that is injected into model module 102 (e.g., the MINLPShaftPower, MINLPActualWork, and v_{MINLPFlow} variables utilized in model module 102). Rather, non-invasive MINLP switch 208 directly forces model-variable module 104 to zero upon switching off and uses the existing behavior of the attached model module 102 to percolate the effects of model-variable module 104 going to zero. This exemplary non-invasive MINLP switch 208 provides additional benefits, including removing the necessity of modifying each process unit or model to make it MINLP-compliant, effecting a workflow that is natural to users of existing ROMEO process definition interfaces (e.g., attaching a non-process unit to a process unit or model and activating and deactivating the non-process unit functionality), and removing the necessity of modifying each MINLP-compliant process unit's user interface to include parameters specific to MINLP implementation (e.g., startup cost, shutdown cost, time period, group ID, group complement, and MINLP activation). In an embodiment, non-invasive MINLP switch 208 enables MINLP behavior for a selected model-variable (e.g., model-variable module 104) in a model (e.g., model module 102) to which it is attached.

In an embodiment, non-invasive MINLP switch 208 of FIG. 2 comprises a storage memory device having stored thereon processor-executable instructions for defining an MINLP switch unit that encodes the MINLP behavior of a first-principle model of a process unit by identifying a model-variable to attach to and modify. In an exemplary embodiment, non-invasive MINLP switch 208 attaches to model module 102 defining a motor, identifies the motor shaft power as the model-variable (e.g., model-variable module 104), and modifies the motor shaft power. In an exemplary embodiment, the non-invasive MINLP switch 208 includes the set of equations:

ModelVariable−MINLPHelperVar1*MINLPSwitch−MINLPHelperVar2=0 (Equation 7)

and

ModelVariable*MINLPSwitch−MINLPHelperVar1=0 (Equation 8)

where Mode/Variable is the model-variable identified by non-invasive MINLP switch 208, MINLPSwitch is a free-independent variable in MINLP Optimization mode bounded by [0, 1], MINLPHelperVar1 is a free-dependent variable that compensates Equation 7, and MINLPHelperVar2 is a dependent variable. Equation 7 ensures that non-invasive MINLP switch 208 is self-sufficient with respect to binary switching and thus requires no additional changes to model module 102. In an embodiment, MINLPSwitch is treated as a free-independent variable that is set by solver module 124. In another embodiment, Equation 7 and Equation 8 provide a well-defined and square (e.g., square Jacobian) model for non-invasive MINLP switch 208.

In both Equations 7 and 8, MINLPHelperVar1 and MINLPHelperVar2 (i.e., the dependent variables) appear linearly. These linear terms contribute a constant in the corresponding Jacobian rows, which ensures that there is no Jacobian row singularity of the switch model (e.g., non-invasive MINLP switch 208) when Mode/Variable and MINLPSwitch both equal zero simultaneously. Furthermore, these linear terms indicate that there is no Jacobian column singularity of the switch model when Mode/Variable and MINLPSwitch both equal zero simultaneously.

Still referring to FIG. 2, model-variable module 104 comprises a storage memory device having stored thereon process-executable instructions for defining a manipulated variable of the first-principle model of model module 102, in an embodiment. Exemplary manipulated variables include, but are not limited to, the shaft power of a motor or generator, the actual work of a steam turbine, and the flow rate of boiler fuel flows. In an embodiment, model-variable module 104 defines Mode/Variable, discussed above.

Referring again to FIG. 2, MINLP interface 112 receives MINLP parameters 110 from a source such as a user, another software program, or a device, for example. The MINLP interface 112 provides received MINLP parameters 110 to non-invasive MINLP switch 208. The non-invasive MINLP switch 208 uses the received MINLP parameters 110 to customize the MINLP behavior that it applies to the first-principle model of the underlying model module 102. The solver module 124 is adapted for changing the value of the MINLPSwitch variable in order to switch model module 102 on and off in the simulation while converging to an optimal solution (e.g., optimal operating state 126) for the underlying nonlinear process 118. In an exemplary embodiment, solver module 124 changes MINLPSwitch and Mode/Variable to optimize (e.g., minimize, maximize, etc.) an objective cost function associated with process 118.

In one embodiment, solver module 124 sets MINLPSwitch to zero (i.e., MINLPSwitch=0). In this case, Equation 7 reduces to:

ModelVariable=MINLPHelperVar2 (Equation 9)

Furthermore, Equation 8 reduces to:

MINLPHelperVar1=0 (Equation 10)

In an embodiment, the lower and upper bounds of MINLPHelperVar2 are set tightly (e.g., [0, 0.00001]) which leads to Mode/Variable=0, as desired. In other words, when MINLPSwitch=0, then Mode/Variable=0. Thus, non-invasive MINLP switch 208 forces the underlying model module 102 to switch off in the simulation as a consequence of Mode/Variable being set to zero. In this manner, non-invasive MINLP switch 208 overrides the routine operation of model module 102. In this embodiment, model module 102, which contains model-variable module 104, which in turn defines ModelVariable, has sufficient degrees of freedom to permit Mode/Variable being equal to zero such that solver module 124 does not encounter a failure state. In other words, there needs to be enough degrees of freedom in model module 102 to absorb the change, ensuring material balance. Additionally, it is necessary to ensure that model module 102 remains robust (i.e., there is no division by zero, or any other non-robust behavior, when the model-variable equals zero).

In another embodiment of the ROMEO solver illustrated by FIG. 2, solver module 124 sets MINLPSwitch to one (i.e., MINLPSwitch=1). In such a case, Equation 7 reduces to:

ModelVariable=MINLPHelperVar1+MINLPHelperVar2 (Equation 11)

Furthermore, Equation 8 reduces to:

ModelVariable=MINLPHelperVar1 (Equation 12)

In an embodiment, MINLPHelperVar2 is held close to zero, as indicated above, and thus Mode/Variable=MINLPHelperVar1 satisfies Equations 11 and 12. In addition, MINLPHelperVar1 inherits the upper bound and lower bound of Mode/Variable that are set by a user. When MINLPSwitch=1, Mode/Variable takes any value between its upper and lower bounds, as decided by solver module 124. Thus, non-invasive MINLP switch 208 allows Mode/Variable to pass through without switching it off and model module 102 performs as designed in the simulation, with the value of Mode/Variable determined by solver module 124 for optimal operation.

In yet another embodiment of the ROMEO solver illustrated by FIG. 2, solver module 124 sets Mode/Variable to zero (i.e., Mode/Variable=0). In such a case, Equation 7 reduces to:

MINLPSwitch*MINLPHelperVar1=−MINLPHelperVar2 (Equation 13)

Furthermore, Equation 8 reduces to:

MINLPHeIperVar1=0 (Equation 14)

When MINLPHelperVar2 is held close to zero and MINLPHelperVar1 is held to the bounds it inherits from Mode/Variable, the only permitted solutions are when MINLPSwitch=0 (e.g., a desired solution) and when the lower bound of MINLPHelperVar1=0. In the situation where MINLPHelperVar1=0, there is a potential ambiguity when MINLPSwitch=1 because there exists a possibility of Mode/Variable=0. Such a case may be referred to as a corner case, in some embodiments, and may be avoided when MINLPHelperVar1 and MINLPHelperVar2 are bounded, as further described herein.

As described above, it is desired in some embodiments to hold MINLPHelperVar2 close to zero, which may be accomplished by setting its lower bound to zero and prescribing a tight upper bound that is close to zero. With respect to MINLPHelperVar1, when MINLPSwitch=1, the bounds of MINLPHelperVar1 are set to equal those of Mode/Variable. By doing so, it is ensured that when MINLPSwitch=1, Mode/Variable takes any value in its permitted range, from its lower bound to its upper bound. Moreover, when the lower bound is greater than zero, then a false solution (e.g., a corner case) cannot arise because MINLPHelperVar1 cannot become equal to zero. In a situation in which MINLPSwitch=0, MINLPHelperVar1 must be permitted to become equal to zero, even if it has a non-zero lower bound, so that Mode/Variable can become equal to zero. This situation is feasible because at the start of a nonlinear solution, the value of MINLPSwitch is known, set by solver module 124, and held constant for the duration of the nonlinear optimization. Thus, at the onset of the nonlinear optimization, a ROMEO solver system embodying aspects of the invention has the liberty to set the lower bound of MINLPHelperVar1 to zero for switches 108, 208 in which MINLPSwitch=0.

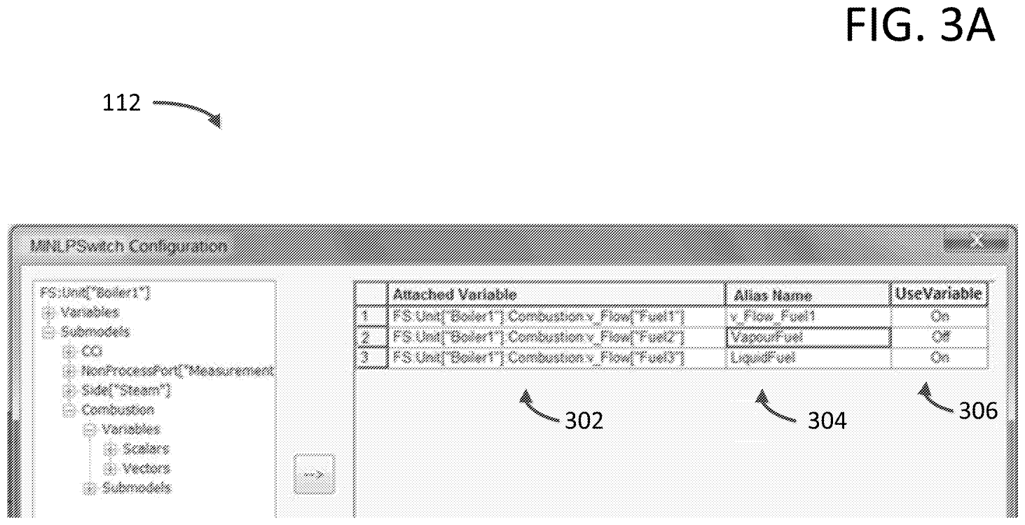

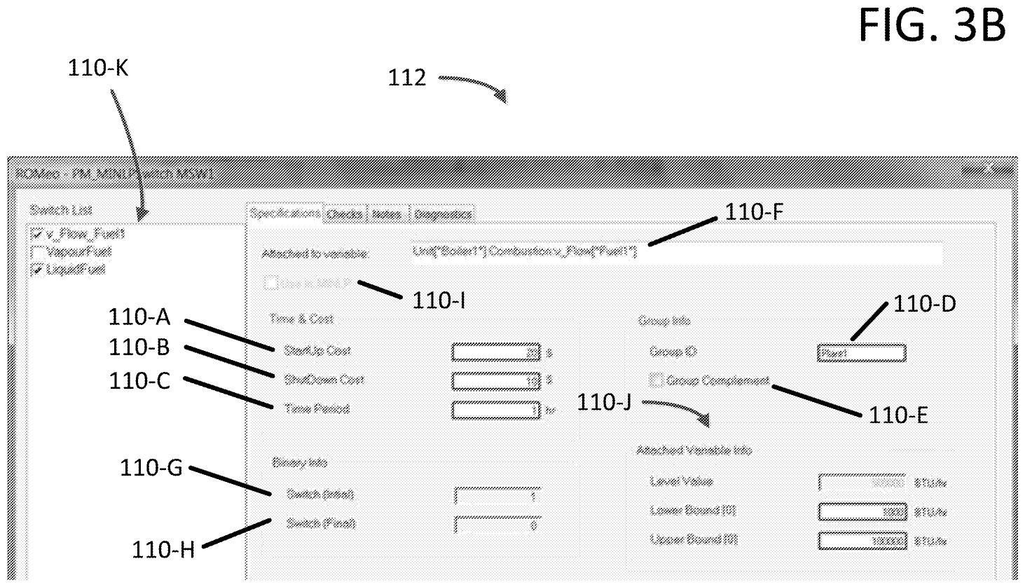

FIGS. 3A and 3B illustrate exemplary MINLP graphical user interfaces (GUI) 112 and MINLP parameters 110 that a user can alter to customize the behavior of invasive MINLP switch 108 and/or non-invasive MINLP switch 208. Referring further to FIG. 3A, a configuration window of MINLP GUI 112 is illustrated. In an embodiment, the configuration window appears on MINLP GUI 112 when a user drops MINLP switch 208 onto model module 102 via MINLP GUI 112. In another embodiment, the configuration window appears on MINLP GUI 112 via invocation of a “Change Configuration” option from a right-click pop-up menu associated with MINLP switch 108, 208. The configuration window facilitates a user in choosing a model variable from a list of supported variables 302. The configuration window further includes an area in which a user can specify an “Alias Name” 304 for a selected model variable. In an embodiment, alias name 304 is used in place of other names for the model variable. For example, alias name 304 may allow a ROMEO solver system embodying aspects of the invention to avoid a lengthy model variable name. In a further embodiment, alias name 304 takes by default a short name of an added variable, which a user may override. In the exemplary embodiment illustrated by FIG. 3A, Row 1 has the default alias name “v_Flow_Fuel1” whereas Rows 2 and 3 have alias names “VapourFuel” and “LiquidFuel” that were overridden by a user. In an embodiment, alias name 304 is comprised of an alphanumeric character and/or an underscore character to comply with MITRE naming conventions and entry of illegal characters results in an error message.

Referring to further aspects of FIG. 3A, the configuration window of MINLP GUI 112 also includes a “Use Variable” option 306 associated with each model variable. In an embodiment, the use variable option 306 allows a user to alter aspects of the variable. In the example illustrated by FIG. 3A, use variable option 306 is set to value “On” for the model variables of Rows 1 and 3 and use variable option 306 is set to value “Off” for the model variable of Row 2. It will be apparent to one skilled in the art that use variable option 306 is distinct from UseInMINLP parameter 110-1, further described herein. In an embodiment in which use variable option 306 is set to value “On,” the associated model variable becomes active and is utilized in an associated MINLP switch (e.g., invasive MINLP switch 108 and/or non-invasive MINLP switch 208). In an embodiment in which use variable option 306 is set to value “Off,” the switch associated with the corresponding model variable becomes inactive and there will not be any MINLP switch equations related to this model variable taking part in the solving operation of solver module 124. The specification of certain parameters (e.g., GroupID, Complement, Time, Cost, etc.) remains preserved for the inactive variables. For example, when a user swaps variables for MINLP action, the user does not need to go through the task of entering all of the information again. According to further aspects, the configuration window of MINLP GUI 112 is referred to as a MINLP manager. In another embodiment, the MINLP manager shows only model variables in which use variable option 306 is set to value “On.” In further embodiments, a model module 102 (e.g., motor, generator, steam turbine, etc.) the associated MINLP switch 108, 208 has only one active variable at a time. In other words, the configuration window will only present one supported variable 302 having its associated use variable option 306 set to value “On.” In such embodiments, MINLP GUI 112 presents a mechanism to restrict and/or warn a user to mark only one of the supported variables 302 with a use variable option 306 of “On.” In yet further embodiments, a model module 102 (e.g., boiler, splitter, source, etc.) has multiple supported variables 302 having associated use variable options 306 set to value “On.”

Referring now to FIG. 3B, a data entry window of MINLP GUI 112 is illustrated. The exemplary MINLP parameters 110 include a startup cost 110-A, a shutdown cost 110-B, a time period 110-C, a group identifier 110-D, a group complement 110-E, a model-variable identifier 110-F, an MINLP module initial value 110-G, an MINLP module final value 110-H, a UseInMINLP parameter 110-I, attached variable parameters 110-J, and a list of model variables 110-K. In alternate embodiments, the MINLP interface 112 and MINLP parameters 110 illustrated by FIG. 3B are used to customize the behavior of invasive MINLP switch 108. In an embodiment, the data entry window appears on MINLP interface 112 when a user double-clicks on invasive MINLP switch 108 and/or non-invasive MINLP switch 208 and allows the user to specify all necessary data for functioning of the MINLP switches 108, 208.

In this exemplary embodiment, a user can set a threshold for switching based upon one or more MINLP parameters 110. In an exemplary embodiment, the startup cost 110-A, the shutdown cost 110-B, and the time period 110-C prevent solver module 124 from switching model module 102 to an operating state that only provides a trivial benefit over a current operating state of process 118. For example, startup cost 110-A, shutdown cost 110-B, and time period 110-C prevent solver module 124 from switching model module 102 indiscriminately in order to achieve an operating state that saves a small amount (e.g., two cents) in operating costs over a current operating state of process 118. In this exemplary embodiment, startup cost 110-A, shutdown cost 110-B, and time period 110-C are converted into a contribution for an objective function used for MINLP by solver module 124. When MINLPBinary is initially equal to one and then is changed to become equal to zero, there is an associated shutdown cost (S_{D}) 110-B. When MINLPBinary is initially equal to zero and then is changed to become equal to one, there is an associated startup cost (S_{U}) 110-A. The contribution to the objective function is represented by the equation:

F(u)=Σᵢ₌₁ⁿ(1−u_{0,i})(uᵢ−u_{0,i})S_{U,i}−u_{0,i}(uᵢ−u_{0,i})S_{D,i} (Equation 15)

where F is a function of the current switching u and also a contribution to the objective function, where n is the number of switches (e.g., changing MINLPBinary from zero to one or from one to zero), and where u₀ is the initial state of MINLPBinary. The following table shows the four cases of interest and the corresponding contribution to the objective function for the case where n is equal to one:

| Initial | Current | Objective |
|---|---|---|
| Switching, | Switching, | Contribution, |
| u_{D} | u | F(u) |
| 0 | 0 | 0 |
| 0 | 1 | S_{U} |
| 1 | 0 | S_{D} |
| 1 | 1 | 0 |

The time period 110-C is assumed to be the period over which the switching is valid and used in such a manner that its contribution can be added to the global objective function of solver module 124 in a dimensionally correct manner.

In a further embodiment of FIG. 3B, the group identifier 110-D is the name of a set of MINLP modules with which non-invasive MINLP switch 208 is associated. All MINLP modules in a set switch on or off (i.e., activate or deactivate) simultaneously, unless they are marked as complements by the group complement 110-E. When non-invasive MINLP switch 208 is marked as a complement by group complement 110-E, it switches in a complementary fashion compared to the rest of the MINLP modules of the set. In other words, the complementary non-invasive MINLP switch 208 will switch on when the other MINLP modules in the set switch off and vice versa. Due to the property of simultaneous switching, individual MINLP modules lose independence and are constrained by the switching of the group to which they belong.

Still referring to FIG. 3B, the model-variable identifier 110-F indicates to which model-variable of model module 102 non-invasive MINLP switch 208 is connected. In the illustrated embodiment, the model-variable is actual work of a steam turbine. Other model-variables include, but are not limited to, the shaft power of a motor, the shaft power of a generator, and the flow rate of boiler fuel flows. The model-variable initial value 110-G is the existing value of the model-variable indicated by model-identifier 110-F. The MINLP module initial value 110-H is the existing value of non-invasive MINLP switch 208 and the MINLP module final value 110-1 is the ending value of non-invasive MINLP switch 208.

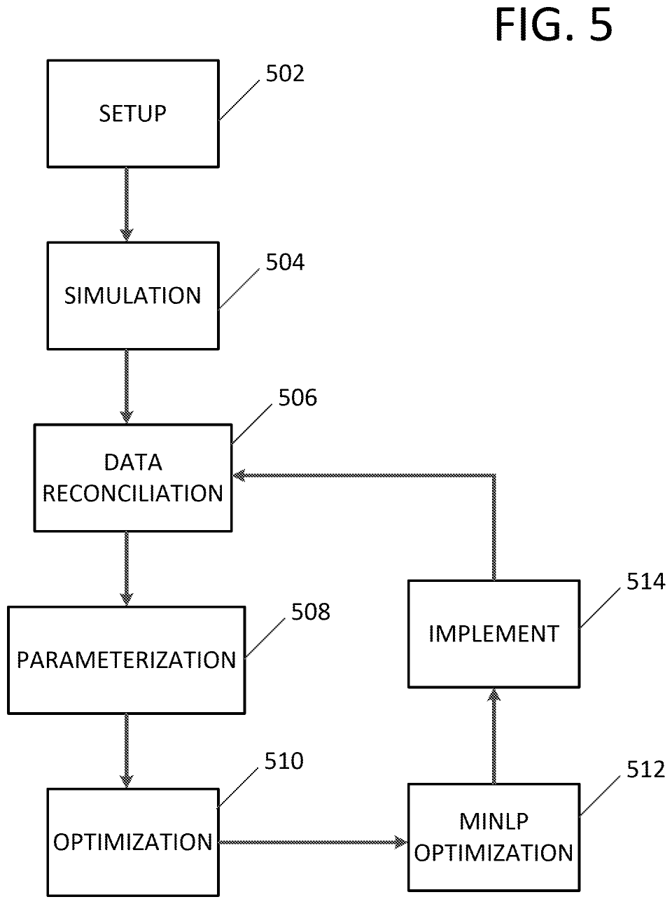

Referring further to the embodiment of FIG. 3B, a user may click on one or more of model variables 110-K to switch between them and enter corresponding data. Attached variable parameters 110-J include a lower bound and an upper bound, which are utilized by solver module 124 in an embodiment. In the illustrated embodiment, UseInMINLP parameter 110-1 is displayed in a read-only mode (e.g., grayed out) and may be altered in the MINLP manager window described above. In an additional embodiment, when a model variable is marked as UseInMINLP (e.g., when UseInMINLP parameter 110-1 is checked), its corresponding binary variable is made free independent and becomes a subject of binary switching by solver module 124. In further embodiments in which a model variable is not marked as UseInMINLP (e.g., UseInMINLP parameter 110-1 is unchecked), the variable's switch will not be treated as MINLP by solver module 124 and it will behave in the way as it behaves in other modes (e.g., those described in connection with FIG. 5). In further embodiments, when there is a solve failure in a MINLP optimization mode (e.g., MINLP optimization mode 512, discussed herein), UseInMINLP parameter 110-1 provides the ability for a user to troubleshoot a flowsheet by unchecking UseInMINLP parameter 110-1 for specific units. For example, this ability saves a user the trouble of going through a wide range of sub-flowsheets before turning a model down and/or off. In yet further embodiments, during a workflow, a user may turn off one or more models based upon the results of solver module 124. After turning the models off, the flowsheet is solved under a simulation mode (e.g., simulation mode 504), a data reconciliation (e.g., data reconciliation mode 506), and an optimization mode (e.g., optimization mode 510), as further described herein. After an entire cycle of a workflow process (e.g., the sample workflow process illustrated by FIG. 5), a user would once again get back to a MINLP optimization mode (e.g., MINLP optimization mode 512). During this operation of the MINLP optimization mode and solver module 124, all MINLP switch units (e.g., invasive MINLP switch 108, non-invasive MINLP switch 208) in which UseInMINLP parameter 110-I is checked (i.e., marked or activated) will be in an active state and become part of the MINLP solvable model. Moreover, the MINLP switch unit turns on its attached model unit during this operation.

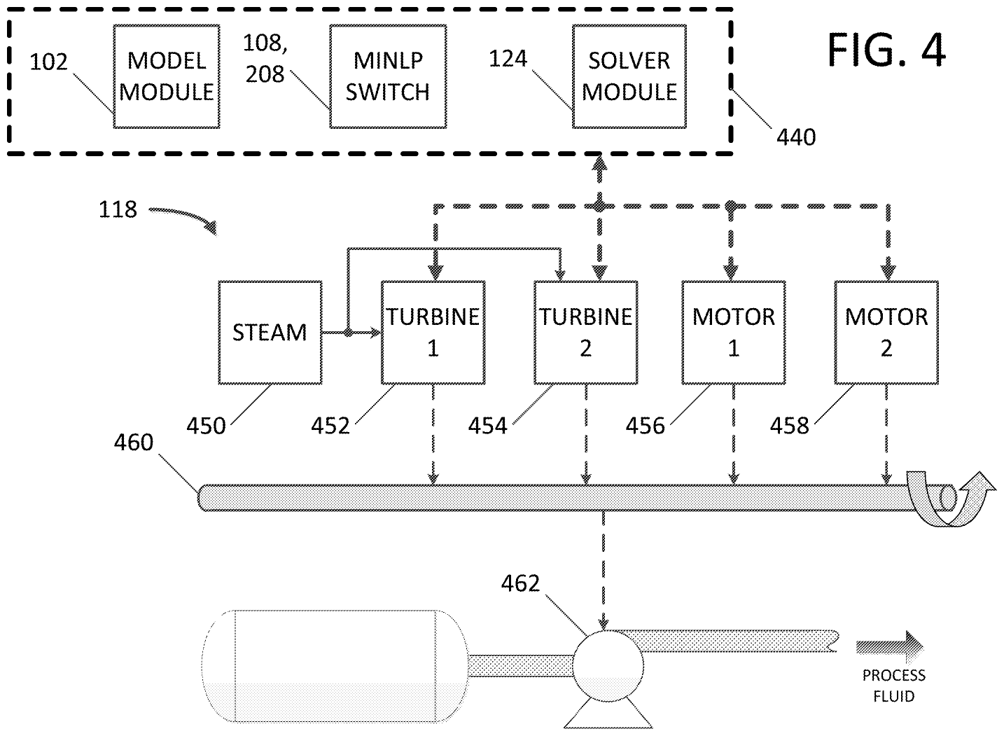

FIG. 4 illustrates an exemplary process 118 including a steam source 450, a first turbine 452, a second turbine 454, a first motor 456, a second motor 458, a shaft 460, and a pump 462. FIG. 4 also illustrates an exemplary control system 440. The exemplary illustrated process 118 is provided to explain how aspects of the present invention, including invasive MINLP switch 108 and non-invasive MINLP switch 208, provide, for example, improvements to the functioning of computing devices and improvements to other technical fields, namely process control and automation of physical industrial plants. It will be apparent to one skilled in the art that aspects of the present invention are capable of optimizing processes other than process 118 and that process 118 is presented for illustration purposes only. The control system 440 is communicatively connected to at least the first turbine 452, the second turbine 454, the first motor 456, and the second motor 458. The steam source 450 is fluidly connected to first turbine 452 and second turbine 454. The first turbine 452, second turbine 454, first motor 456, and second motor 458 are each mechanically connected to the shaft 460, which in turn is mechanically connected to the pump 462.

The control system 440 manages the operation of process 118 and in an exemplary embodiment includes at least model module 102, solver module 124, and invasive MINLP switch 108 and/or non-invasive MINLP switch 208. In additional exemplary embodiments, control system 440 is one of a distributed control system (DCS) and a centralized database run in an online mode. The control system 440 is adapted for transmitting control information to process 118 and receiving sensory and feedback data from process 118. For example, control system 440 and process 118 may communicate via a telecommunications network that facilitates the exchange of data, such as those that operate according to the IEEE 802.3 (e.g., Ethernet) and/or the IEEE 802.11 (e.g., Wi-Fi) protocols, for example. In another embodiment, control system 440 and process 118 communicate via any medium that allows data to be physically transferred through serial or parallel communication channels (e.g., copper wire, optical fiber, computer bus, wireless communication channel, etc.).

The steam source 450 provides steam to power first turbine 452 and second turbine 454. In an embodiment, steam source 450 is a boiler and captured steam is provided to first turbine 452 and second turbine 454 via pipes or ducts. The first motor 456 and second motor 458 are powered by electricity. The first turbine 452, second turbine 454, first motor 456, and second motor 458 are each capable of driving shaft 460 to power pump 462, which pumps a process fluid from a tank.

FIG. 5 illustrates a sample workflow process in a ROMEO-based solver. The process includes a setup step 502, a simulation mode 504, a data reconciliation 506, a parameterization 508, an optimization mode 510, an MINLP optimization mode 512, and an implementation step 514. In an embodiment, the simulation mode 504, the data reconciliation mode 506, the optimization mode 510, and the MINLP optimization mode 512 are modes of operation of a ROMEO-based solver, such as solver module 124.

Initially at setup step 502, models and specifications for the solver are created. In an exemplary embodiment, process 118 is physically modeled by model module 102 via process definition interface 122, specifies MINLP parameters 110 for invasive MINLP switch 108 and/or non-invasive MINLP switch 208 via MINLP interface 110, and specifies constraint input data 114 for constraint module 106 via constraint interface 116. In another embodiment, process 118 is modeled using predefined ROMEO unit operations, such as simple mixers, splitters, flash drums, complete distillation columns, and reactors. In yet a further embodiment, process 118 is modeled a custom unit operation created by a user via process definition interface 122. After setup step 502 is complete, the process advances to simulation mode 504.

During simulation mode 504, solver module 124 solves the model that was created at setup step 502. In an embodiment, solver module 124 converts the physical model into a single mathematical model and solves the mathematical model using non-linear matrix arithmetic. This solution method offers considerable time saving and permits aspects of the invention to serve as a real-time simulation tool. Also during simulation mode 504, the free-independent variables of invasive MINLP switch 108 and non-invasive MINLP switch 208 (e.g., MINLPSwitch) are set to fixed-independent. For example, these variables can either be fixed at zero (e.g., MINLPSwitch=0) or fixed at one (e.g., MINLPSwitch=1) based upon the results of a previous data-reconciliation exercise (e.g., a previous operation of data reconciliation 506). After simulation mode 504 is complete, the process advances to data reconciliation 506.

During data reconciliation, 506 solver module 124 brings the physical model into harmony with actual observed operating conditions of process 118. In an exemplary embodiment, sensors within process 118 obtain measurements of various operating conditions of the process (e.g., temperature, pressure, composition, and flow rate) and transmit data including the measurements to solver module 124. Solver module 124 receives the data and reconciles redundant and/or inconsistent measurements using established algorithms for evaluating the validity of observed process data (e.g., data collected by sensors of process 118). Based on reconciled observed data, solver module 124 modifies and/or adjusts process model unit specifications and parameters (e.g., model module 102, MINLP parameters 110, constraint input data 114, etc.) to make the process model conform even more closely to observed reality (e.g., measured operating conditions of process 118).

In an embodiment of data reconciliation 506, solver module 124 interfaces directly with a distributed control system (e.g., control system 440) or centralized database associated with process 118 and run in an online mode. In such an embodiment, no user input is required. In another embodiment, measurement values are supplied manually via a user interface (e.g., process definition interface 122, MINLP interface 112, constraint interface 116, etc.) and data reconciliation 506 executes in an offline mode. Also during data reconciliation 506, the free-independent variables of invasive MINLP switch 108 and non-invasive MINLP switch 208 (e.g., MINLPSwitch) are set to fixed-independent. For example, these variables can either be fixed at zero (e.g., MINLPSwitch=0) or fixed at one (e.g., MINLPSwitch=1) based upon the results of a previous data-reconciliation exercise (e.g., a previous operation of data reconciliation 506). After data reconciliation 506 is complete, the process advances to parameterization 508.

During parameterization 508, solver module 124 turns off the MINLPSwitch (e.g., MINLPSwitch=0) for every invasive MINLP switch 108 and non-invasive MINLP switch 208 whose corresponding model module 102 is determined to be off. In an exemplary embodiment, solver module 124 auto-runs a macro for this purpose. Also during parameterization 508, the free-independent variables of invasive MINLP switch 108 and non-invasive MINLP switch 208 (e.g., MINLPSwitch) are set to fixed-independent. For example, these variables can either be fixed at zero (e.g., MINLPSwitch=0) or fixed at one (e.g., MINLPSwitch=1) based upon the results of a previous data-reconciliation exercise (e.g., a previous operation of data reconciliation 506). After parameterization 508 is complete, the process advances to optimization mode 510.

During optimization mode 510, solver module 124 assigns monetary values to pertinent process variables and adjusts controller setpoints to maximize the economics of process 118. Examples of monetary assignments include greater values for preferred stream fractions compared to less desirable fractions, bonuses for additional octane points in a product, or a monetary penalty for each part per million (ppm) of a contaminant or undesirable compound in a stream. In an embodiment, solver module 124 operating in optimization mode 510 provides a systematic fashion for determining economic connectivity between unit setpoints, specifications, and operating conditions of process 118 that would otherwise remain undetected and unexploited. Also during optimization mode 510, the free-independent variables of invasive MINLP switch 108 and non-invasive MINLP switch 208 (e.g., MINLPSwitch) are set to fixed-independent. For example, these variables can either be fixed at zero (e.g., MINLPSwitch=0) or fixed at one (e.g., MINLPSwitch=1) based upon the results of a previous data-reconciliation exercise (e.g., a previous operation of data reconciliation 506). After optimization mode 510 is complete, the process advances to MINLP optimization mode 512.

During MINLP optimization mode 512, solver module 124 switches invasive MINLP switch 108 and/or non-invasive MINLP switch 208 on and off (e.g., MINLPSwitch=0, MINLPSwitch=1) to determine an operating state of process 118 that is optimized and satisfies process constraints. Also during MINLP optimization mode 512, the formerly fixed-independent variables of invasive MINLP switch 108 and non-invasive MINLP switch 208 (e.g., MINLPSwitch) are set to free-independent, which permits solver module 124 to move them appropriately (e.g., change their values) to obtain an optimal solution for the operating state of process 118. Further aspects of MINLP optimization mode 512 are described below. After MINLP optimization mode 512 is complete, the process advances to implementation step 514.

During the implementation step 514, solver module 124 implements the optimal solution for the operating state of process 118 into the model module 102. After implementation step 514 is complete, the process advances to data reconciliation step 506. In an embodiment, after MINLP optimization mode 512 is complete and its results are communicated to process 118 and implemented during implementation step 514, in subsequent cycles of data reconciliation 506 and optimization mode 510, any switched-off (i.e., inactive) units are removed from the calculations in these modes. Such switched-off units will be awakened (i.e., activated) in the next cycle of MINLP optimization mode 512 to be considered again for switching on or off.

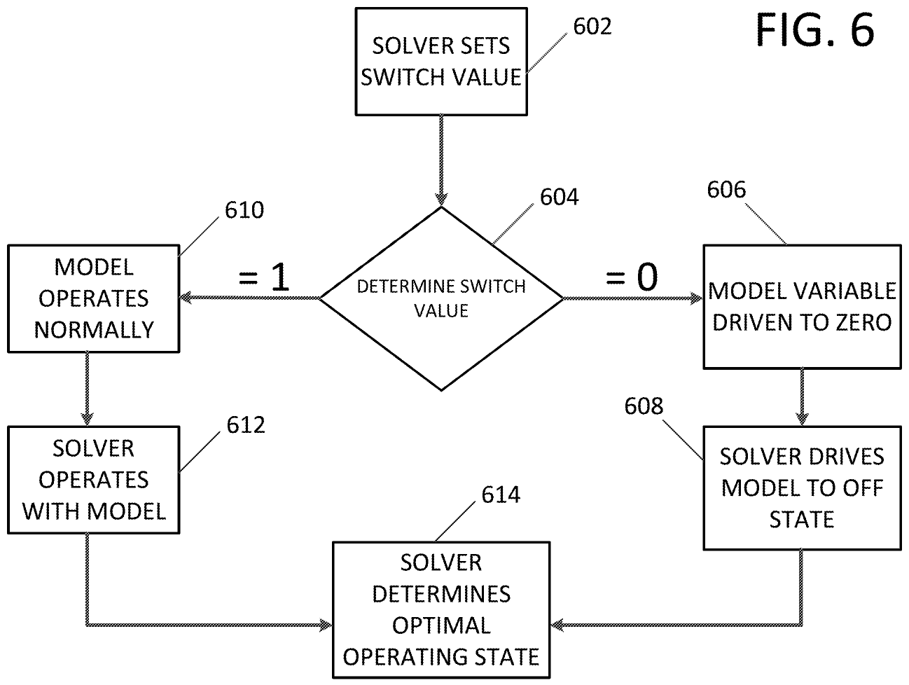

FIG. 6 illustrates an exemplary embodiment of non-invasive MINLP switch 208 operating in MINLP optimization mode 512. During step 602 of the process, solver module 124 sets a value that indicates whether a model module 102 corresponding to non-invasive MINLP switch 208 will be turned on or turned off. At step 604, non-invasive MINLP switch 208 determines that switch value. If the switch value is equal to zero, then non-invasive MINLP switch 208 drives the corresponding model module 102 to zero at step 606. The process then advances to step 608 where solver module 124 drives the model module 102 to an off state to determine an optimal operating state of process 118 at step 614. Referring back to step 604, if the switch value is equal to one then non-invasive MINLP switch 208 does not turn the corresponding model module 102 off. In other words, the model module 102 operates normally at step 610. The process then advances to step 612 where solver module 124 operates with the model module 102 to determine an optimal operating state of process 118 at step 614.

Although the above description of FIG. 6 references operation with non-invasive MINLP switch 208, it is to be understood by one skilled in the art that invasive MINLP switch 108 may also be utilized in such a process. In one embodiment, invasive MINLP switch 108 and/or non-invasive MINLP switch 208 enable solver module 124 to determine which energy sources of process 118 both optimize the process and satisfy process constraints by switching MINLP models on and off. In another embodiment, invasive MINLP switch 108 and/or non-invasive MINLP switch 208 enable solver module 124 to determine an operating state of process 118 that is optimized and satisfies process constraints by simulating operation of process 118 via process unit models in conjunction with an MINLP solver.

Embodiments of the present invention may comprise a special purpose computer including a variety of computer hardware, as described in greater detail below.

Embodiments within the scope of the present invention also include computer-readable media for carrying or having computer-executable instructions or data structures stored thereon. Such computer-readable media can be any available media that can be accessed by a special purpose computer. By way of example, and not limitation, such computer-readable media can comprise RAM, ROM, EEPROM, CD-ROM or other optical disk storage, magnetic disk storage, or other magnetic storage devices, or any other medium that can be used to carry or store desired program code means in the form of computer-executable instructions or data structures and that can be accessed by a general purpose or special purpose computer. When information is transferred or provided over a network or another communications connection (either hardwired, wireless, or a combination of hardwired or wireless) to a computer, the computer properly views the connection as a computer-readable medium. Thus, any such connection is properly termed a computer-readable medium. Combinations of the above should also be included within the scope of computer-readable media. Computer-executable instructions comprise, for example, instructions and data which cause a general purpose computer, special purpose computer, or special purpose processing device to perform a certain function or group of functions.

The following discussion is intended to provide a brief, general description of a suitable computing environment in which aspects of the invention may be implemented. Although not required, aspects of the invention will be described in the general context of computer-executable instructions, such as program modules, being executed by computers in network environments. Generally, program modules include routines, programs, objects, components, data structures, etc. that perform particular tasks or implement particular abstract data types. Computer-executable instructions, associated data structures, and program modules represent examples of the program code means for executing steps of the methods disclosed herein. The particular sequence of such executable instructions or associated data structures represent examples of corresponding acts for implementing the functions described in such steps.

Those skilled in the art will appreciate that aspects of the invention may be practiced in network computing environments with many types of computer system configurations, including personal computers, hand-held devices, multi-processor systems, microprocessor-based or programmable consumer electronics, network PCs, minicomputers, mainframe computers, and the like. Aspects of the invention may also be practiced in distributed computing environments where tasks are performed by local and remote processing devices that are linked (either by hardwired links, wireless links, or by a combination of hardwired or wireless links) through a communications network. In a distributed computing environment, program modules may be located in both local and remote memory storage devices.

An exemplary system for implementing aspects of the invention includes a special purpose computing device in the form of a conventional computer, including a processing unit, a system memory, and a system bus that couples various system components including the system memory to the processing unit. The system bus may be any of several types of bus structures including a memory bus or memory controller, a peripheral bus, and a local bus using any of a variety of bus architectures. The system memory includes read only memory (ROM) and random access memory (RAM). A basic input/output system (BIOS), containing the basic routines that help transfer information between elements within the computer, such as during start-up, may be stored in ROM. Further, the computer may include any device (e.g., computer, laptop, tablet, PDA, cell phone, mobile phone, a smart television, and the like) that is capable of receiving or transmitting an IP address wirelessly to or from the internet.

The computer may also include a magnetic hard disk drive for reading from and writing to a magnetic hard disk, a magnetic disk drive for reading from or writing to a removable magnetic disk, and an optical disk drive for reading from or writing to removable optical disk such as a CD-ROM or other optical media. The magnetic hard disk drive, magnetic disk drive, and optical disk drive are connected to the system bus by a hard disk drive interface, a magnetic disk drive-interface, and an optical drive interface, respectively. The drives and their associated computer-readable media provide nonvolatile storage of computer-executable instructions, data structures, program modules, and other data for the computer. Although the exemplary environment described herein employs a magnetic hard disk, a removable magnetic disk, and a removable optical disk, other types of computer readable media for storing data can be used, including magnetic cassettes, flash memory cards, digital video disks, Bernoulli cartridges, RAMs, ROMs, solid state drives (SSDs), and the like.

The computer typically includes a variety of computer readable media. Computer readable media can be any available media that can be accessed by the computer and includes both volatile and nonvolatile media, removable and non-removable media. By way of example, and not limitation, computer readable media may comprise computer storage media and communication media. Computer storage media include both volatile and nonvolatile, removable and non-removable media implemented in any method or technology for storage of information such as computer readable instructions, data structures, program modules or other data. Computer storage media are non-transitory and include, but are not limited to, RAM, ROM, EEPROM, flash memory or other memory technology, CD-ROM, digital versatile disks (DVD) or other optical disk storage, SSDs, magnetic cassettes, magnetic tape, magnetic disk storage or other magnetic storage devices, or any other medium which can be used to store the desired non-transitory information, which can accessed by the computer. Alternatively, communication media typically embody computer readable instructions, data structures, program modules or other data in a modulated data signal such as a carrier wave or other transport mechanism and includes any information delivery media.

Program code means comprising one or more program modules may be stored on the hard disk, magnetic disk, optical disk, ROM, and/or RAM, including an operating system, one or more application programs, other program modules, and program data. A user may enter commands and information into the computer through a keyboard, pointing device, or other input device, such as a microphone, joy stick, game pad, satellite dish, scanner, or the like. These and other input devices are often connected to the processing unit through a serial port interface coupled to the system bus. Alternatively, the input devices may be connected by other interfaces, such as a parallel port, a game port, or a universal serial bus (USB). A monitor or another display device is also connected to the system bus via an interface, such as video adapter 48. In addition to the monitor, personal computers typically include other peripheral output devices (not shown), such as speakers and printers.

One or more aspects of the invention may be embodied in computer-executable instructions (i.e., software), routines, or functions stored in system memory or non-volatile memory as application programs, program modules, and/or program data. The software may alternatively be stored remotely, such as on a remote computer with remote application programs. Generally, program modules include routines, programs, objects, components, data structures, etc. that perform particular tasks or implement particular abstract data types when executed by a processor in a computer or other device. The computer executable instructions may be stored on one or more tangible, non-transitory computer readable media (e.g., hard disk, optical disk, removable storage media, solid state memory, RAM, etc.) and executed by one or more processors or other devices. As will be appreciated by one of skill in the art, the functionality of the program modules may be combined or distributed as desired in various embodiments. In addition, the functionality may be embodied in whole or in part in firmware or hardware equivalents such as integrated circuits, application specific integrated circuits, field programmable gate arrays (FPGA), and the like.

The computer may operate in a networked environment using logical connections to one or more remote computers. The remote computers may each be another personal computer, a tablet, a PDA, a server, a router, a network PC, a peer device, or other common network node, and typically include many or all of the elements described above relative to the computer. The logical connections include a local area network (LAN) and a wide area network (WAN) that are presented here by way of example and not limitation. Such networking environments are commonplace in office-wide or enterprise-wide computer networks, intranets and the Internet.

When used in a LAN networking environment, the computer is connected to the local network through a network interface or adapter. When used in a WAN networking environment, the computer may include a modem, a wireless link, or other means for establishing communications over the wide area network, such as the Internet. The modem, which may be internal or external, is connected to the system bus via the serial port interface. In a networked environment, program modules depicted relative to the computer, or portions thereof, may be stored in the remote memory storage device. It will be appreciated that the network connections shown are exemplary and other means of establishing communications over wide area network may be used.

Preferably, computer-executable instructions are stored in a memory, such as the hard disk drive, and executed by the computer. Advantageously, the computer processor has the capability to perform all operations (e.g., execute computer-executable instructions) in real-time.

The order of execution or performance of the operations in embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

Embodiments of the invention may be implemented with computer-executable instructions. The computer-executable instructions may be organized into one or more computer-executable components or modules. Aspects of the invention may be implemented with any number and organization of such components or modules. For example, aspects of the invention are not limited to the specific computer-executable instructions or the specific components or modules illustrated in the figures and described herein. Other embodiments of the invention may include different computer-executable instructions or components having more or less functionality than illustrated and described herein.

When introducing elements of aspects of the invention or the embodiments thereof, the articles “a”, “an”, “the” and “said” are intended to mean that there are one or more of the elements. The terms “comprising”, “including”, and “having” are intended to be inclusive and mean that there may be additional elements other than the listed elements.

Having described aspects of the invention in detail, it will be apparent that modifications and variations are possible without departing from the scope of aspects of the invention as defined in the appended claims. As various changes could be made in the above constructions, products, and methods without departing from the scope of aspects of the invention, it is intended that all matter contained in the above description and shown in the accompanying drawings shall be interpreted as illustrative and not in a limiting sense.

1-20. (canceled)

21. A system for process optimization using Mixed Integer Nonlinear Programming (MINLP) comprising:
one or more computers comprising one or more processors and one or more non-transitory processor readable media, the one or more non-transitory processor readable media comprising instructions that when executed by the one or more processors implement a control system, the control system configured to:
receive, by the one or more processors, data representing a current state of a process unit from a sensor in an industrial process;
execute, by the one or more processors, a simulation of at least one unit model representing the process unit via at least one equation using the data representing the current state of the process unit; and
initiate, by the one or more processors, a switch to change the at least one unit model between an active state and an inactive state;
wherein the switch comprises implementing a MINLP switch configured to simulate the at least one unit model representing the process unit as being in the inactive state while the process unit remains in the active state.

22. The system of claim 21,
wherein the at least one equation includes an unbounded free-dependent variable, the unbounded free-dependent variable being equal to a free-independent variable bounded by [0, 1] multiplicatively combined with a model-variable of the at least one unit model;
wherein the at least one unit model is in the active state when the free-independent variable is equal to 1, and wherein the at least one unit model is in the inactive state when the free-independent variable is equal to 0; and
wherein binding the free-independent variable by [0, 1] allows the model-variable to update as the current state of the process unit changes during operation of the process while simultaneously allowing the unbounded free-dependent variable to simulate the process unit being turned off in the simulation without turning off the process unit in the process.

23. The system of claim 22,
wherein the one or more non-transitory processor readable media comprise further instructions that cause the control system to:
execute, by the one or more processors, a data reconciliation configured to bring the at least one unit model into harmony with actual operating conditions of the process; and
adjust, based on the actual operating conditions, the at least one unit model to make the at least one unit model to conform more closely to the actual operating conditions.

24. The system of claim 22,
wherein the MINLP switch comprises the at least one equation including the model-variable, the free-independent variable bounded by [0, 1] and the unbounded free-dependent variable.

25. The system of claim 24,
wherein the at least one unit model is in the active state when the free-independent variable is equal to one, and wherein the at least one unit model is in the inactive state when the free-independent variable is equal to zero.

26. The system of claim 24,
wherein implementing the MINLP switch further comprises implementing the at least one equation according to one or more MINLP parameters, wherein the one or more MINLP parameters comprise a threshold for switching the at least one unit model between the active state and the inactive state.

27. The system of claim 22,
wherein the control system comprises a model module,
wherein the model module is configured to execute the at least one equation.

28. The system of claim 27,
wherein the at least one equation comprises a first-principles model.

29. A system for process optimization using Mixed Integer Nonlinear Programming (MINLP) comprising:
one or more computers comprising one or more processors and one or more non-transitory processor readable media, the one or more non-transitory processor readable media comprising instructions that when executed by the one or more processors implement a control system, the control system comprising:
a model module,
an MINLP switch, and
a solver module;
wherein the model module is configured to:
execute, by the one or more processors, a simulation of at least one unit model representing a process unit via at least one equation using data received by a sensor to represent a current state of the process unit in a process;
wherein the model module is configured to:
define, by the one or more processors, a first-principles model that is configured to implement MINLP behavior for the process unit;
wherein the MINLP switch is configured to:
implement, by the one or more processors, an MINLP behavior in the first-principles model of the model module while the current state of the process unit is not altered in the process;
wherein the solver module is configured to:
interface, by the one or more processors, with the model module to determine an optimal operating state of the process unit; and
wherein the solver module controls a state of the model module via the MINLP switch.

30. The system of claim 29,
wherein the at least one equation includes an unbounded free-dependent variable, the unbounded free-dependent variable being equal to a free-independent variable bounded by [0, 1] multiplicatively combined with a model-variable of the first-principles model;
wherein the at least one unit model is in an active state when the free-independent variable is equal to 1, and wherein the at least one unit model is in an inactive state when the free-independent variable is equal to 0; and
wherein binding the free-independent variable by [0, 1] allows the model-variable to update as the current state of the process unit changes during operation of the process while simultaneously allowing the unbounded free-dependent variable to simulate the process unit being turned off in the simulation without turning off the process unit in the process.

31. The system of claim 30,
wherein the first-principles model includes the unbounded free-dependent variable.

32. The system of claim 31,
wherein the model module is in the active state when the free-independent variable is equal to 1, and wherein the model module is in the inactive state when the free-independent variable is equal to 0.

33. The system of claim 32,
wherein the process unit is not altered while the model module is in the inactive state.

34. The system of claim 30,
wherein the solver module sets a value of the free-independent variable during an execution of the solver module.

35. A system for process optimization using Mixed Integer Nonlinear Programming (MINLP) comprising:
one or more computers comprising one or more processors and one or more non-transitory processor readable media, the one or more non-transitory processor readable media comprising instructions that when executed by the one or more processors implement a control system, the control system comprising:
a model module configured to generate a simulation including a unit model representing a process unit in a process via at least one first-principles model;
an MINLP switch configured to transition the model module between an active state and an inactive state during an execution of a switch module; and
a solver module configured to operate with the model module to determine an optimal operating state of the process unit;
wherein the model module is configured to receive data representing a current state of the process unit from at least one sensor and use the data in the unit model;
wherein the MINLP switch is configured to define an MINLP switch unit that encodes an MINLP behavior to the at least one first-principles model of the process unit by identifying a model-variable to attach to and modify; and
wherein the MINLP switch is configured to simulate the process unit as being in the inactive state while the process unit remains in the active state.

36. The system of claim 35,
wherein the at least one first-principles model includes an unbounded free-dependent variable, the unbounded free-dependent variable being equal to a free-independent variable bounded by [0, 1] multiplicatively combined with a model-variable of the at least one first-principles model; and
wherein binding the free-independent variable by [0, 1] allows the model-variable to update as the current state of the process unit changes during operation of the process while simultaneously allowing the unbounded free-dependent variable to simulate the process unit being turned off in the simulation without turning off the process unit in the process.

37. The system of claim 36,
wherein the at least one first-principles model is in the active state when the free-independent variable is equal to 1, and wherein the at least one first-principles model is in the inactive state when the free-independent variable is equal to 0.

38. The system of claim 37,
wherein the process unit continues to operate in the process while the model module is in the inactive state.

39. The system of claim 35,
wherein the solver module is configured to implement an optimal solution for an operating state of the process unit.

40. The system of claim 35,
wherein the MINLP switch is configured to encode the MINLP behavior of the model module.
